(19) United States
(12) Patent Application Publication
(10) Pub. No.: US 2017/0346418 A1
(43) Pub. Date: Nov. 30, 2017

(54) CHUCKING DEVICE AND VACUUM PROCESSING APPARATUS

(71) Applicant: ULVAC, INC., Chigasaki-shi (JP)

(72) Inventors: Ken MAEHIRA, Chigasaki-shi (JP); Kou FUWA, Chigasaki-shi (JP); Tomohiro HAYASAKA, Chigasaki-shi (JP)

(73) Assignee: ULVAC, INC., Chigasaki-shi (JP)

(21) Appl. No.: 15/673,849

(22) Filed: Aug. 10, 2017

Related U.S. Application Data
(63) Continuation of application No. PCT/JP2016/060669, filed on Mar. 31, 2016.

(30) Foreign Application Priority Data
Apr. 2, 2015 (JP) 2015-075939

(51) Int. Cl. H02N 13/00; H01J 37/34; C23C 14/50; H01L 21/683; C23C 14/34

(52) U.S. Cl. CPC H02N 13/00; H01L 21/6831; C23C 14/34; C23C 14/50; H01J 37/3411

(57) ABSTRACT

The present invention provides a technology for reducing the attractive force of a chucking device at its surface contacting an object to be chucked to thereby eliminate or minimize the generation of dust when chucking and removing the object, and to enable control for making the attractive force of the chucking device uniform. The chucking device of the present invention includes: a main body portion 50 constituted by a dielectric and pairs of chucking electrodes 11 and 12 for attracting and holding a substrate 10, the pairs of chucking electrodes 11 and 12 being provided in the dielectric, each of the pairs of chucking electrodes 11 and 12 being opposite in polarity; and a plurality of conductive films 51 arranged on a part of the main body portion 50 on the chucking side relative to the pairs of chucking electrodes 11 and 12 in such a manner as to respectively span across a positive electrode 11a and a negative electrode 11b constituting the pair of chucking electrodes 11 and across a positive electrode 12a and a negative electrode 12b constituting the pair of chucking electrodes 12.

### TECHNICAL FIELD

The present invention generally relates to a chucking device for attracting and holding a substrate in a vacuum, and more specifically, a technology of a chucking device for attracting and holding a substrate having an insulating film on the back surface thereof, or an insulating substrate.

### BACKGROUND ART

Conventionally, electrostatic chucking devices are widely used to perform precise control of the temperature of substrates in sputtering apparatuses or other apparatuses. In an apparatus for performing processing such as film formation of a film onto an insulating substrate such as glass in a vacuum, a chucking device that uses a gradient force to attract and hold the insulating substrate is widely used. For electrostatic chucking of a substrate having an insulating film on the back surface thereof, techniques to enhance the attractive force (such as, increasing the chucking voltage) are employed.

For the chucking device of this kind, conventionally, a contact of the chucking surface of the chucking device with the back surface of the substrate results in flaking of the material of the back surface of the substrate or of the chucking surface, thus generating dust that causes process defects.

This has been a factor responsible for reduced reliability of the device, such as a reduction in yield in the course of manufacture.

In the conventional art, attractive force is enhanced to reduce thermal resistance at the contact portion (interface) between the substrate and the chucking surface, in which case the surface of the substrate or the chucking surface of the chucking device is polished to enhance adhesion (increase the area of contact) at the contact portion, and as a result, abrasion dust builds up. To cope with this problem, there is a need for reducing the attractive force at the contact portion.

On the other hand, the chucking device as a whole needs to be reduced in terms of thermal resistance to the substrate. Thus, there has been a need for a technique to enhance the attractive force at non-contacting portions while reducing the attractive force at the contact portion, and to reduce thermal resistance by using gas-assisted heat transfer or other heat transfer means.

Further, the reduction in residual attractive force after completion of chucking has conventionally been accomplished by the technique of relatively reducing the in-plane attractive force, such as simply reducing the area of chucking or reducing applied voltage.

However, such an approach reduces the performance of heat transfer between the substrate and the chucking device, thus causing the device to be unable to fully perform its original chucking capability.

Further, reductions in throughput time of the device, for example, have resulted in problems such as transfer errors due to remaining residual attraction, or reduction in yield for each wafer, and there has thus been a demand for controlling the chucking device to provide uniform attractive force.

Still further, the attractive force at the portion contacting the substrate can induce flaking at the back surface of the substrate or the surface of the chucking device. Thus, in addition to the provision for uniform attractive force, it has also been desired to lower the attractive force at the contact portion to thereby eliminate or minimize abrasion or flaking.

On the other hand, any attempts to make uniform the attractive force may cause some of a plurality of chucking electrodes to suffer a short circuit therebetween. To avoid such a situation, it has also been desired to reduce the attractive force at some of the chucking electrodes.

### RELATED ART DOCUMENT

### Patent Document

Patent Document 1: JP 4342691 B2

### SUMMARY OF INVENTION

### Problems to be Solved by the Invention

The present invention has been made to solve the foregoing problems of the conventional art, and has an objective to provide a technology that enables reducing the attractive force of a chucking device at its surface contacting an object to be chucked to thereby eliminate or minimize the generation of dust when chucking and removing the object, and enables control to make the attractive force of the chucking device uniform as a whole and to locally reduce the attractive force.

It is another objective of the present invention to provide a technology that enables the chucking device as a whole to reduce thermal resistance between the chucking device and an object being chucked.

### Means for Solving the Problems

To accomplish the above objectives, the present invention provides a chucking device including: a main body portion constituted by a dielectric and a plurality of pairs of chucking electrodes for attracting and holding an object to be chucked, the plurality of pairs of chucking electrodes being provided in the dielectric, each pair of chucking electrodes being opposite in polarity; and a plurality of conductive films arranged on a part of the main body portion on the chucking side relative to the plurality of pairs of chucking electrodes in such a manner as to span across a positive electrode and a negative electrode constituting each pair of chucking electrodes.

The present invention is also effective in the case where the plurality of conductive films are arranged to provide the positive electrode and the negative electrode constituting each pair of chucking electrodes with equal areas of shielding from an electric field generated by the pair of chucking electrodes.

The present invention is also effective in the case where the main body portion is provided with contact support portions projecting from the chucking-side surface of the main body portion, the contact support portions being configured to come into contact with and support the object to be chucked, and the conductive films are disposed only within regions over which the contact support portions extend.

The present invention is also effective in the case where the contact support portions are formed integrally with and of the same material as the main body portion.

The present invention is also effective in the case where the chucking device includes a conductive-film-equipped sheet constituted by an insulating sheet and the conductive films provided on the inner side of the insulating sheet, the conductive-film-equipped sheet being configured to form the contact support portions when placed on the surface of the main body portion and configured to be freely attachable to and detachable from the main body portion.

As another aspect, the present invention provides a vacuum processing apparatus including a vacuum chamber and any of the above-described chucking devices provided in the vacuum chamber, the vacuum processing apparatus being configured to perform a predetermined processing on the object attracted and held by the chucking device.

### Advantageous Effect of the Invention

The chucking device of the present invention includes: a main body portion constituted by a dielectric and a plurality of pairs of chucking electrodes for attracting and holding an object to be chucked, the plurality of pairs of chucking electrodes being provided in the dielectric, each pair of chucking electrodes being opposite in polarity; and a plurality of conductive films arranged on a part of the main body portion on the chucking side relative to the plurality of pairs of chucking electrodes in such a manner as to span across a positive electrode and a negative electrode constituting each pair of chucking electrodes. This configuration allows an electric field generated between positive and negative electrodes constituting the plurality of pairs of chucking electrodes to be shielded in the regions over which the plurality of conductive films extend, and generates no situation where each conductive film itself assumes a potential. This eliminates the generation of attractive force at the locations of the plurality of conductive films on the chucking side of the main body portion.

Consequently, the present invention eliminates or minimizes the occurrence of flaking at the object being chucked and the surface of the chucking device resulting from, for example, friction at the portions of the chucking device contacting the object, and as a result, prevents the generation of dust and increases the lifetime of the chucking device itself.

Further, the present invention enables control to make the attractive force of the chucking device uniform at each region, and also enables control and adjustment of the distribution state of the attractive force in the chucking surface. The invention thus prevents errors in transferring the object being chucked and avoids reduction of yields.

Still further, even in the event that some of the plurality of pairs of chucking electrodes suffer a short circuit between the paired electrodes, the present invention enables control to reduce the attractive force at the shorted pair of chucking electrodes. The present invention thereby avoids and prevents the occurrence of a short circuit between two electrodes constituting each pair of chucking electrodes.

In the present invention, in the case where the plurality of conductive films are arranged to provide the positive electrode and the negative electrode constituting each pair of chucking electrodes with equal areas of shielding from an electric field generated by the pair of chucking electrodes, it is possible to perform control to make the attractive force more uniform in the regions of the main body portion of the chucking device where the plurality of pairs of chucking electrodes are arranged. Further, the areas of the plurality of conductive films over the chucking electrodes, the plurality of conductive films spanning across the positive and negative electrodes constituting the plurality of pairs of chucking electrodes, may be arranged to have a distribution on the surface of the main body portion. In this case, it is possible to control the attractive force and residual attractive force resulting therefrom.

In the present invention, in the case where the main body portion is provided with contact support portions projecting from the chucking-side surface of the main body portion and configured to come into contact with and support the object to be chucked, and the conductive films spanning across the positive and negative electrodes constituting the chucking electrodes of the main body portion as described above are disposed only within regions over which the contact support portions extend, it is possible to preclude the generation of attractive force at the contact support portions, and thus possible to reduce friction resistance resulting from, for example, heat at the contact portions between the main body portion and the object. Further, by increasing the attractive force at non-contacting portions between the main body portion and the object, it is possible to reduce thermal resistance between the chucking device and the object through the use of gas-assisted heat transfer or other heat transfer means, without causing a reduction in the attractive force of the chucking device as a whole.

In this case, if the contact support portions are formed integrally with and of the same material as the main body portion, the manufacturing process is simplified and, because of the use of integral molding, the mechanical strength (such as, stiffness) is enhanced when compared to the case of manufacture by bonding.

Further, in the case where: the chucking device includes a conductive-film-equipped sheet constituted by an insulating sheet and the conductive films provided on the inner side of the insulating sheet; the conductive-film-equipped sheet is placed on the surface of the main body portion and contact support portions are thereby formed to span across the positive electrode and the negative electrode constituting the chucking electrodes of the main body portion; and the conductive-film-equipped sheet is configured to be freely attachable to and detachable from the main body portion, it is possible to replace the conductive films easily, and thus possible to provide a chucking device that is easy-to-maintain, usable for a variety of objects to be chucked and thus adaptable to a wide variety of applications.

In addition, a vacuum processing apparatus including any of the above-described chucking devices provided in a vacuum chamber and configured to perform a predetermined processing on an object attracted and held by the chucking device is capable of performing high-quality vacuum processing.

### BRIEF DESCRIPTION OF DRAWINGS

FIG. 1 is a schematic configuration diagram of a sputtering apparatus which is one embodiment of a vacuum processing apparatus according to the present invention.

FIG. 2(a) is a schematic configuration diagram illustrating a cross section of a chucking device of the entire-surface chucking type; and FIG. 2(b) is an equivalent circuit diagram illustrating the principle of chucking of a substrate.

FIGS. 3(a) and 3(b) schematically illustrate a configuration example of a chucking device according to the present invention, FIG. 3(a) being a cross-sectional configuration diagram, and FIG. 3(b) being a plan configuration diagram.

FIG. 4 is a cross-sectional configuration diagram schematically illustrating another configuration example of the chucking device according to the present invention.

FIGS. 5(a) and 5(b) are cross-sectional configuration diagrams schematically illustrating another configuration example of the chucking device according to the present invention.

FIGS. 6(a) and 6(b) are cross-sectional configuration diagrams schematically illustrating another configuration example of the chucking device according to the present invention.

### DESCRIPTION OF EMBODIMENTS

Preferred embodiments of the present invention will now be described in detail with reference to the drawings.

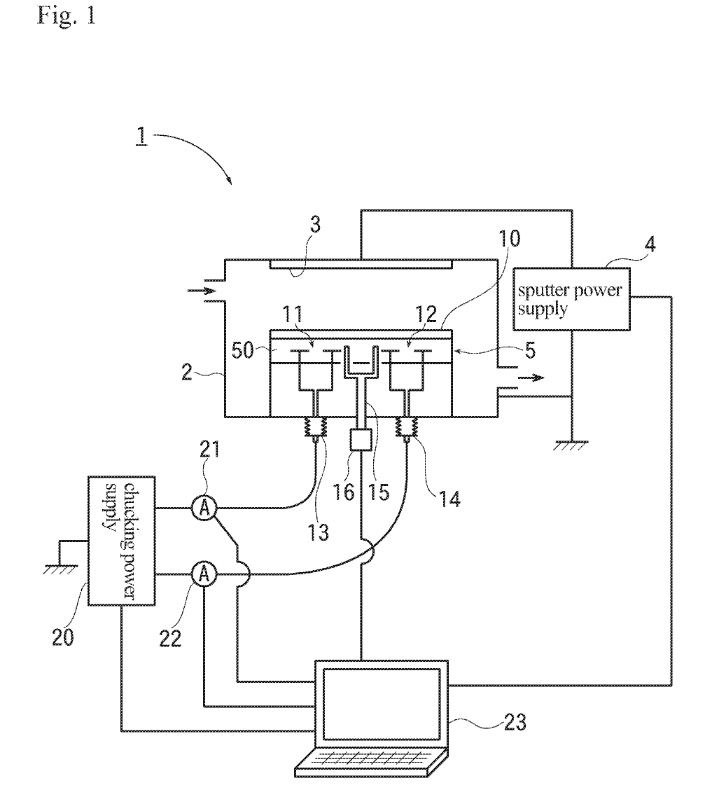

FIG. 1 is a schematic configuration diagram of a sputtering apparatus as one embodiment of a vacuum processing apparatus according to the present invention.

In FIG. 1, reference numeral 2 indicates a vacuum chamber of the sputtering apparatus, generally referred to by reference number 1, of the present embodiment. The vacuum chamber 2 is connected to a vacuum evacuation system (not shown) and configured to let a sputter gas in.

A target 3 serving as a film formation source is provided on the inner top side of the vacuum chamber 2.

The target 3 is connected to a sputter power supply 4 and configured to be supplied with a negative bias voltage. The positive side of the sputter power supply 4 is grounded together with the vacuum chamber 2.

A chucking device 5 for attracting and holding a substrate (an object to be chucked) 10 is provided in the vacuum chamber 2.

The chucking device 5 is of the bipolar type, and includes a main body portion 50 formed of a dielectric such as a variety of ceramics, and a plurality of (two in the present embodiment) pairs of chucking electrodes 11 and 12 provided in the main body portion 50. The chucking device 5 is configured so that the chucking electrodes 11 and 12 are supplied with power from a chucking power supply 20 provided outside the vacuum chamber 2 via current introduction terminals 13 and 14, respectively.

Ammeters 21 and 22 capable of measuring extremely small currents are connected between the chucking power supply 20 and the current introduction terminals 13 and 14, respectively.

On the other hand, an elevator mechanism 15 for placing the substrate 10 on the chucking device 5 or removing the substrate 10 from the chucking device 5 is provided at the bottom of the vacuum chamber 2.

A computer 23 for controlling the entire apparatus is provided outside the vacuum chamber 2. The computer 23 is connected to a drive section 16 for driving the aforementioned elevator mechanism 15, and to the ammeters 21 and 22, the chucking power supply 20 and the sputter power supply 4.

The computer 23 includes an A/D converter board and other components, and is connected to a means for recording currents such as a pen recorder (not shown).

The principle of the present invention will now be described.

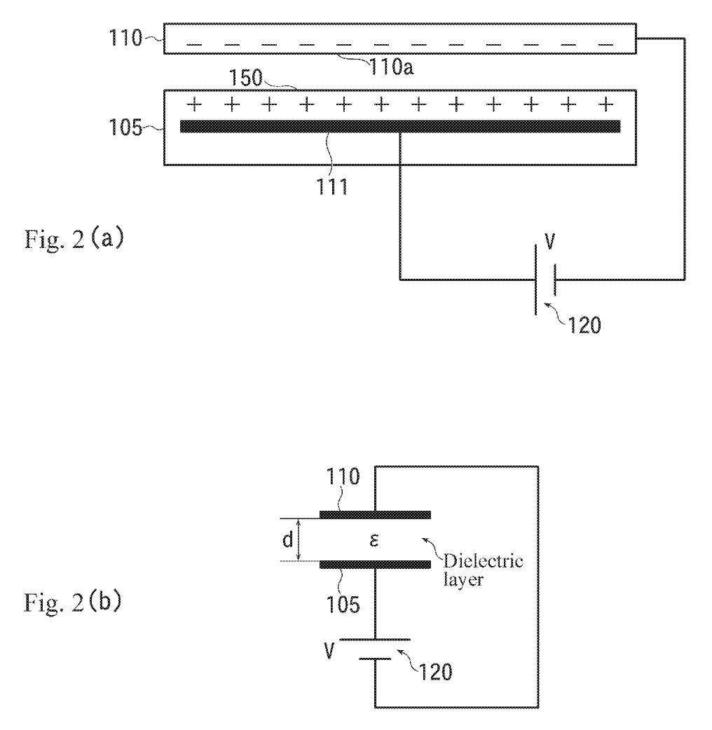

FIG. 2(a) is a schematic configuration diagram illustrating a cross section of a chucking device of the entire-surface chucking type.

As shown in FIG. 2(a), by applying a predetermined voltage V from a chucking power supply 120 to between a substrate 110 and a chucking electrode 111 provided in a chucking device 105 formed of a dielectric, electrical charges of opposite polarities are generated at a chucking surface 150 of the chucking device 105 and a back surface 110a of the substrate 110; and as a result, the chucking surface 150 of the chucking device 105 and the back surface 110a are bound by Coulomb force, so that the substrate 110 is held on the chucking surface 150.

FIG. 2(b) is an equivalent circuit diagram illustrating the principle of chucking of a substrate.

First, Coulomb force Fc will be considered to calculate attractive force F. If ∈ denotes the permittivity of the dielectric layer of the chucking device 105, V denotes the applied voltage, d denotes the distance created by the dielectric layer, and S denotes the area of electrically charged portions of the substrate 110 and the chucking device 105, the following formula holds:

Fc=½·∈·S(V/d)².

For an actual chucking device, Coulomb force Fc generated with a dielectric as a capacitor and Johnson-Rahbeck force Fjr generated by a flow of a small current through an extremely small area between the substrate and the chucking electrode are added up. As a result, attractive force F to act between the chucking device and the substrate is expressed by the following formula:

F=Fc+Fjr.

In general, Johnson-Rahbeck force is known to be relatively larger than Coulomb force.

It is also known that Coulomb force and Johnson-Rahbeck force depend on the volume resistivity of the dielectric, and Johnson-Rahbeck force predominates in the range of low resistivity (1×10¹² Ω·cm or less), whereas Coulomb force predominates in the range of high resistivity (1×10¹³ Ω·cm or more).

As a method for controlling attractive force at the interface between the substrate and the chucking device, a thin conductor film can be formed on the chucking surface to interrupt dielectric polarization between the substrate and the chucking device.

However, in the case of a chucking device that uses Johnson-Rahbeck force described above, when the substrate is formed of, e.g., an oxide film, a small current flowing through the dielectric causes electrical charges to move to the thin conductor film itself to generate a chucking force with the oxide film on the chucking-side surface of the substrate as a dielectric, resulting in no reduction in attractive force.

The present invention has been made on the basis of the above findings.

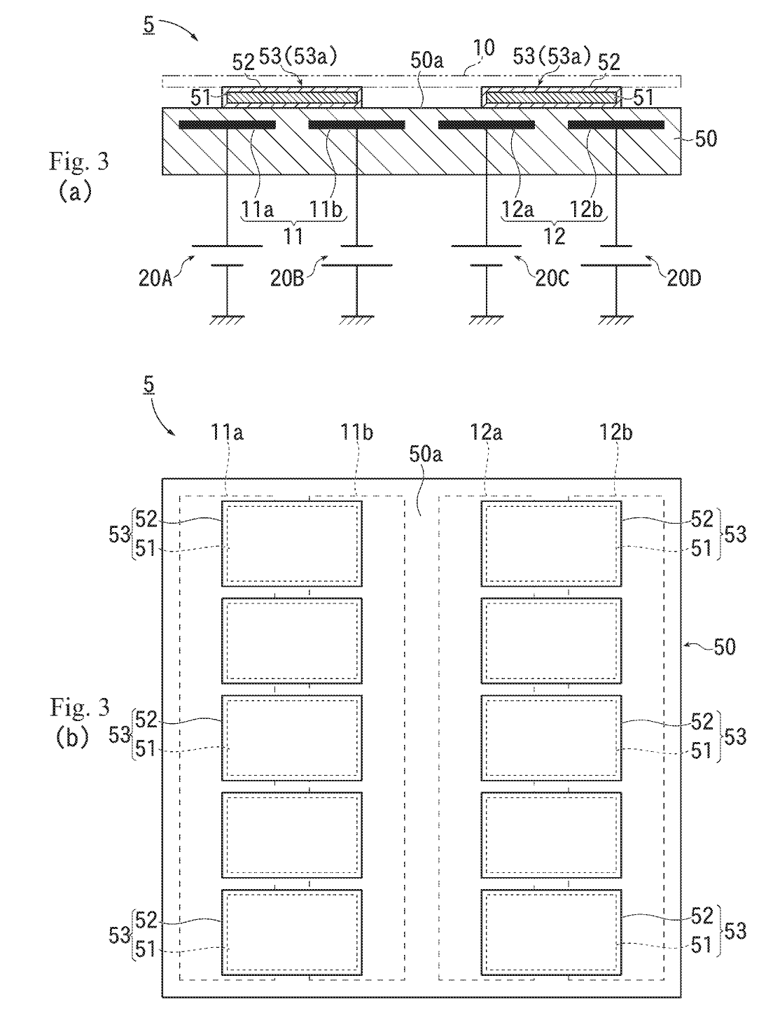

FIGS. 3(a) and 3(b) are schematic diagrams that illustrate a configuration example of the chucking device according to the present invention, FIG. 3(a) being a cross-sectional configuration diagram, and FIG. 3(b) being a plan configuration diagram.

As shown in FIG. 3(a), the chucking device, generally referred to by reference number 5, of this configuration example is of the bipolar type, and is constructed by providing a pair of chucking electrodes 11 (positive electrode 11a and negative electrode 11b) and a pair of chucking electrodes 12 (positive electrode 12a and negative electrode 12b) in the main body portion 50 formed of a dielectric and shaped like, for example, a rectangular plate.

The pairs of chucking electrodes 11 and 12 are respectively connected to chucking power supplies 20A and 20B of different polarities, and 20C and 20D of different polarities. The chucking power supplies 20A and 20B, and 20C and 20D are configured to be independently controllable.

In this configuration example, as shown in FIG. 3(b), the pair of chucking electrodes 11 (positive electrode 11a and negative electrode 11b) and the pair of chucking electrodes 12 (positive electrode 12a and negative electrode 12b) are shaped into rectangles of the same size and arranged at predetermined intervals.

The chucking device 5 includes conductive films 51 arranged on a part of the main body portion 50 on the chucking side relative to the pairs of chucking electrodes 11 and 12 in such a manner as to span across the positive electrode 11a and the negative electrode 11b constituting the pair of chucking electrodes 11 and across the positive electrode 12a and the negative electrode 12b constituting the pair of chucking electrodes 12.

In this configuration example, each conductive film 51 has a rectangular shape, and the periphery thereof is covered with an insulating protector 52 to thereby form a conductive film unit 53a in the shape of a block (see FIG. 3(a)).

A plurality of conductive film units 53a are provided on the surface 50a of the main body portion 50, a number of them being assigned to each of the pairs of chucking electrodes 11 and 12 and arranged along the longitudinal direction of the pairs of chucking electrodes 11 and 12. This provides contact support portions 53 projecting from the surface 50a of the main body portion 50.

The substrate 10 is to be placed on the contact support portions 53 of the main body portion 50. More specifically, in this configuration example, the substrate 10 is to be brought into contact with and supported by the top ends of the contact support portions 53.

In the present invention, from the viewpoint of generating electric fields evenly between the electrodes of opposite polarities constituting the pairs of chucking electrodes 11 and 12, the conductive films 51 are preferably arranged to provide the positive electrode 11a and the negative electrode 11b constituting the pair of chucking electrodes 11 and the positive electrode 12a and the negative electrode 12b constituting the pair of chucking electrodes 12 with equal areas of shielding from the electric fields generated by the respective pairs of chucking electrodes 11 and 12, although not specifically limited thereto. More specifically, the conductive films 51 preferably extend over equal distances with equal overlapping areas in the chucking direction for the positive electrode 11a and the negative electrode 11b constituting the pair of chucking electrodes 11, and for the positive electrode 12a and the negative electrode 12b constituting the pair of chucking electrodes 12.

The aforementioned insulating protectors 52 may be omitted; however, they are preferably provided from the viewpoint of preventing the substrate 10 to be chucked from becoming contaminated with metal, and protecting the conductive films 51.

In the present invention, materials employable for the conductive films 51 are high-melting-point metals or metal nitrides (e.g., titanium (Ti), tantalum (Ta), niobium (Nb), titanium nitride (TiN), and tantalum nitride (TaN)). In addition, other so-called metals can be used without problems, and non-metal materials that have a resistivity of 1×10³ Ω·cm or less are also usable in the present invention.

In the present invention, the main body portion 50 may be a sintered body and the conductive films 51 may undergo sintering together with the main body portion 50. In this case, for preventing the conductive films 51 from melting during the manufacture thereof and for neutralizing the electric fields generated by the pairs of chucking electrodes 11 and 12 with reliability, it is preferable to use a material having a melting point higher than or equal to the sintering temperature of the main body portion 50 and having a volume resistivity of 1×10¹⁰ Ω·cm, although not specifically limited thereto, as the material of the conductive films 51.

The conductive films 51 can be formed by a film-deposition process (such as, PVD, CVD or vapor deposition). Commercially available sheet-type conductive films may also be used.

As described above, the chucking device 5 of this configuration example has the plurality of conductive films 51 arranged on a part of the main body portion 50 on the chucking side relative to the two pairs of chucking electrodes 11 and 12 in such a manner as to span across the positive electrode 11a and the negative electrode 11b constituting the pair of chucking electrodes 11 and across the positive electrode 12a and the negative electrode 12b constituting the pair of chucking electrode 12. As a result, an electric field generated between the positive electrode 11a and the negative electrode 11b constituting the pair of chucking electrodes 11 and an electric field generated between the positive electrode 12a and the negative electrode 12b constituting the pair of chucking electrodes 12 are each shielded in the regions over which the plurality of conductive films 51 extend, and no situation is generated where each conductive film 51 itself assumes a potential. This eliminates the generation of attractive force at the locations of the plurality of conductive films 51 on the chucking side of the main body portion 50.

Consequently, this configuration example eliminates or minimizes the occurrence of flaking at the substrate 10 and the surface 50a of the main body portion 50 of the chucking device 5 resulting from, for example, friction at the portions of the chucking device 5 contacting the substrate 10, and as a result, prevents the generation of dust and increases the lifetime of the chucking device 5 itself.

Further, this configuration example enables control to make the attractive force of the chucking device 5 uniform, and also enables control and adjustment of the distribution state of the attractive force in the chucking surface. This configuration thus prevents errors in transferring the substrate 10 and avoids any reduction in yield.

Still further, even in the event that one of the two pairs of chucking electrodes 11 and 12 suffers a short circuit, this configuration example enables control to reduce the attractive force generated by one of the pairs of chucking electrodes 11 and 12, and thereby avoids and prevents the occurrence of a short circuit between two electrodes constituting the pair of chucking electrodes 11 or 12.

In this configuration example, in particular, the conductive films 51 are arranged to provide the positive electrode 11a and the negative electrode 11b constituting the pair of chucking electrodes 11 and the positive electrode 12a and the negative electrode 12b constituting the pair of chucking electrodes 12 with equal areas of shielding from the electric fields generated by the respective pairs of chucking electrodes 11 and 12. This configuration thus enables control so that the attractive force becomes uniform in the regions of the main body portion 50 of the chucking device 5 where the pairs of chucking electrodes 11 and 12 are arranged.

Further, in this configuration example, the conductive films 51 are disposed only within the contact support portions 53 of the main body portion 50 for supporting the substrate 10. This configuration precludes the generation of attractive force at the contact support portions 53, and thus reduces friction resistance resulting from, for example, heat at the contact portions between the main body portion 50 and the substrate 10. Further, by increasing the attractive force at non-contacting portions between the main body portion 50 and the substrate 10, it is possible to reduce thermal resistance between the entire chucking device 5 and the substrate 10 through the use of gas-assisted heat transfer or other heat transfer means, without causing a reduction in the attractive force of the chucking device 5 as a whole.

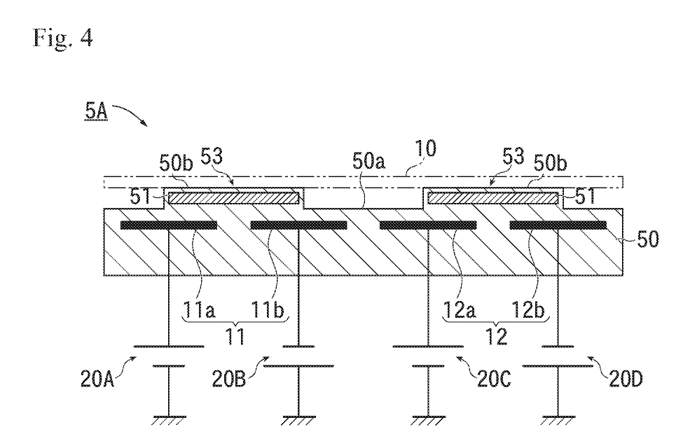

FIG. 4 is a cross-sectional schematic diagram illustrating another configuration example of the chucking device according to the present invention. Parts corresponding to those of the foregoing configuration example will hereinafter be designated by identical reference numerals, and a detailed description thereof will be omitted.

As shown in FIG. 4, the chucking device, generally referred to by reference number 5A, of this configuration example includes the main body portion 50 of the foregoing chucking device 5 and a plurality of contact support portions 53 projecting from the surface 50a of the main body portion 50, with the above-described conductive films 51 provided in the contact support portions 53. The plurality of contact support portions 53 are formed by projections 50b which are formed integrally with and of the same material as the main body portion 50.

The contact support portions 53 of the main body portion 50 have their respective top ends formed to be flat and located at the same level with respect to the surface 50a of the main body portion 50.

Further, the conductive films 51 are disposed in such a manner as to span across the positive electrode 11a and the negative electrode 11b constituting the pair of chucking electrodes 11 and across the positive electrode 12a and the negative electrode 12b constituting the pair of chucking electrodes 12.

The substrate 10 is to be placed on the contact support portions 53 of the main body portion 50. More specifically, the substrate 10 is to be brought into contact with and supported by the top ends of the contact support portions 53 projecting from the main body portion 50.

This configuration example having such a configuration not only provides the foregoing effects but also simplifies the manufacturing process because a plurality of contact support portions 53 formed integrally with and of the same material as the main body portion 50 are provided so as to project from the surface 50a of the main body portion 50 of the chucking device 5A and the conductive films 51 are provided in those contact support portions 53. Further, since this configuration example uses integral molding, mechanical strength (such as, stiffness) is enhanced as compared to the case of manufacture by bonding.

Further, in this configuration example, the conductive films 51 are disposed only within the contact support portions 53 of the main body portion 50. This configuration precludes the generation of attractive force at the contact support portions 53, and thus reduces friction resistance resulting from, for example, heat at the contact portions between the main body portion 50 and the substrate 10. Further, by increasing the attractive force at non-contacting portions between the main body portion 50 and the substrate 10, it is possible to reduce thermal resistance between the entire chucking device 5A and the substrate 10 through the use of gas-assisted heat transfer or other heat transfer means, without causing a reduction in the attractive force of the chucking device 5A as a whole.

The other configuration, function and effects are the same as those of the foregoing configuration example, and a detailed description thereof will thus be omitted.

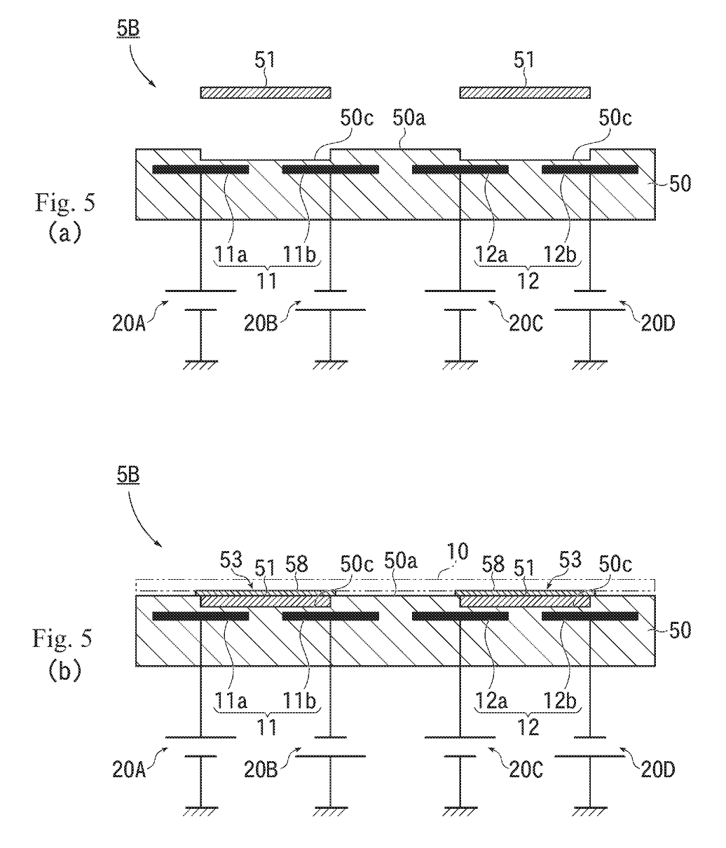

FIGS. 5(a) and 5(b) are cross-sectional configuration diagrams schematically illustrating another configuration example of the chucking device according to the present invention. Parts corresponding to those of the foregoing configuration example will hereinafter be designated by identical reference numerals, and a detailed description thereof will be omitted.

As shown in FIGS. 5(a) and 5(b), the chucking device, generally referred to by reference number 5B, of this configuration example includes the main body portion 50 of the foregoing chucking device 5 with a plurality of recesses 50c in the surface 50a of the main body portion 50, the recesses 50c having a size and shape corresponding to the size and shape of the above-described conductive films 51.

The recesses 50c of the main body portion 50 are provided to extend across the positive electrode 11a and the negative electrode 11b of the pair of chucking electrodes 11 and across the positive electrode 12a and the negative electrode 12b of the pair of chucking electrode 12.

By such a configuration, when the conductive films 51 are placed in the respective corresponding recesses 50c in the main body portion 50, the conductive films 51 are to span across the positive electrode 11a and the negative electrode 11b of the pair of chucking electrodes 11 and across the positive electrode 12a and the negative electrode 12b of the pair of chucking electrode 12.

In this configuration example, after the conductive films 51 are placed in the respective corresponding recesses 50c in the main body portion 50, the respective surfaces of the conductive films 51 are preferably covered with, e.g., sheet-type protective films 58 to thereby form contact support portions 53 on the surface 50a of the main body portion 50, as shown in FIG. 5(b).

This configuration example having such a configuration not only provides the foregoing effects but also simplifies the manufacturing process because the conductive films 51 are configured to be disposed in the recesses 50c formed in the surface 50a of the main body portion 50 of the chucking device 5B.

Further, in this configuration example, the conductive films 51 are disposed only below the protective films 58 provided on the main body portion 50 (that is, only within the regions over which the contact support portions 53 extend). This configuration precludes the generation of attractive force at the contact support portions 53, and thus reduces friction resistance resulting from, for example, heat at the contact portions between the main body portion 50 and the substrate 10. Further, by increasing the attractive force at non-contacting portions between the main body portion 50 and the substrate 10, it is possible to reduce thermal resistance between the entire chucking device 5B and the substrate 10 through the use of gas-assisted heat transfer or other heat transfer means, without causing a reduction in the attractive force of the chucking device 5B as a whole.

The other configuration, function and effects are the same as those of the foregoing configuration example, and a detailed description thereof will thus be omitted.

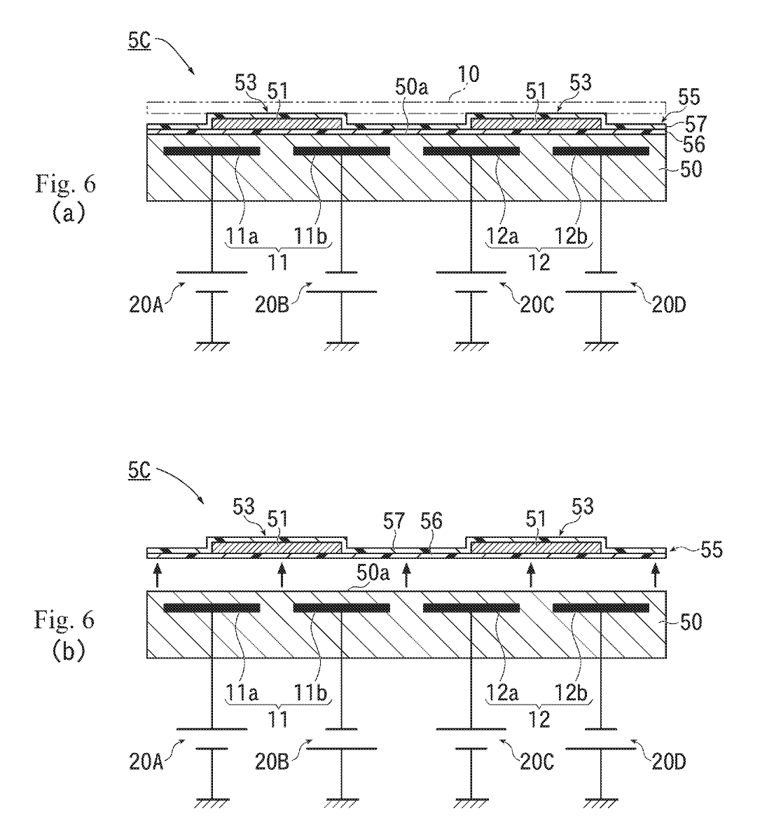

FIGS. 6(a) and 6(b) are cross-sectional schematic diagrams illustrating another configuration example of the chucking device according to the present invention. Parts corresponding to those of the foregoing configuration example will hereinafter be designated by identical reference numerals, and a detailed description thereof will be omitted.

As shown in FIGS. 6(a) and 6(b), the chucking device, generally referred to by reference number 5C, of this configuration example includes the main body portion 50 of the foregoing chucking device 5, and an insulating sheet 55 incorporating the above-described conductive films 51 (hereinafter referred to as “conductive-film-equipped sheet”) provided on the surface 50a of the main body portion 50.

The conductive-film-equipped sheet 55 is constituted by a sheet base 56 formed of, e.g., resin, the conductive films 51 provided on the sheet base 56, and a protective sheet 57 formed of, e.g., resin, covering the conductive films 51.

The sheet base 56 has the same size as the surface 50a of the main body portion 50, and the plurality of conductive films 51 are provided thereon. Thus, the conductive-film-equipped sheet 55 is configured to form the contact support portions 53 as described above when placed on the surface 50a of the main body portion 50.

Further, the conductive-film-equipped sheet 55 is configured so that when placed on the surface 50a of the main body portion 50, the conductive films 51 extend to span across the positive electrode 11a and the negative electrode 11b constituting the pair of chucking electrodes 11 and across the positive electrode 12a and the negative electrode 12b constituting the pair of chucking electrodes 12.

The conductive-film-equipped sheet 55 of this configuration example is bonded to the surface 50a of the main body portion 50 with an adhesive, and is configured to be freely attachable to and detachable from the surface 50a of the main body portion 50.

This configuration example having such a configuration not only provides the foregoing effects but also facilitates replacement of the conductive films 51 because of the provision of the conductive-film-equipped sheet 55 which is freely attachable to and detachable from the surface 50a of the main body portion 50. As a result, it is possible to provide a chucking device that is easy-to-maintain, usable for a variety of objects to be chucked and thus, adaptable to a wide variety of applications.

Further, in this configuration example, the conductive films 51 are disposed only within the contact support portions 53 formed by the conductive-film-equipped sheet 55 provided on the main body portion 50. This configuration precludes the generation of attractive force at the contact support portions 53, and thus reduces friction resistance resulting from, for example, heat at the contact portions between the main body portion 50 and the substrate 10. Further, by increasing the attractive force at non-contacting portions between the main body portion 50 and the substrate 10, it is possible to reduce thermal resistance between the entire chucking device 5C and the substrate 10 through the use of gas-assisted heat transfer or other heat transfer means, without causing a reduction in the attractive force of the chucking device 5C as a whole.

The other configuration, function and effects are the same as those of the foregoing configuration example, and a detailed description thereof will thus be omitted

The present invention is not limited to the above-described embodiments, and various modifications may be made thereto.

For example, the shapes and numbers of the chucking electrodes 11 and 12, the conductive films 51 and the contact support portions 53 described in the foregoing embodiments are examples and can be modified in various ways without departing from the scope of the present invention.

Further, the present invention is applicable not only to sputtering apparatuses but also to various vacuum processing apparatuses such as vapor deposition apparatuses and etching apparatuses.

### DESCRIPTION OF THE REFERENCE NUMERALS

1: sputtering apparatus (vacuum processing apparatus), 2: vacuum chamber, 3: target, 4: sputter power supply, 5: chucking device, 10: substrate (object to be chucked), 11, 12: chucking electrode, 11a, 12a: positive electrode, 11b, 12b: negative electrode, 20A, 20B, 20C, 20D: chucking power supply, 50: main body portion, 50a: surface, 51: conductive film, 52: protector, 53: contact support portion

1. A chucking device, comprising:
a main body portion constituted by a dielectric and a plurality of pairs of chucking electrodes for attracting and holding an object to be chucked, the plurality of pairs of chucking electrodes being provided in the dielectric, each pair of the chucking electrodes being opposite in polarity; and
a plurality of conductive films arranged on a part of the main body portion on a chucking side relative to the plurality of pairs of chucking electrodes in such a manner as to span across a positive electrode and a negative electrode constituting each pair of the chucking electrodes.

2. The chucking device according to claim 1, wherein the plurality of conductive films are arranged to provide the positive electrode and the negative electrode constituting each pair of chucking electrodes with equal areas of shielding from an electric field generated by the pair of chucking electrodes.

3. The chucking device according to claim 1, wherein the main body portion is provided with contact support portions projecting from a chucking-side surface of the main body portion, the contact support portions being configured to come into contact with and support the object to be chucked, and wherein the conductive films are disposed only within regions over which the contact support portions extend.

4. The chucking device according to claim 3, wherein the contact support portions are formed integrally with and of the same material as the main body portion.

5. The chucking device according to claim 3, further comprising a conductive-film-equipped sheet constituted by an insulating sheet and the conductive films provided on an inner side of the insulating sheet, the conductive-film-equipped sheet being configured to form the contact support portions when placed on the surface of the main body portion and configured to be freely attachable to and detachable from the main body portion.

6. A vacuum processing apparatus, comprising:
a vacuum chamber; and
a chucking device provided in the vacuum chamber,
the chucking device including:
a main body portion constituted by a dielectric and a plurality of pairs of chucking electrodes for attracting and holding an object to be chucked, the plurality of pairs of chucking electrodes being provided in the dielectric, each pair of the chucking electrodes being opposite in polarity; and
a plurality of conductive films arranged on a part of the main body portion on a chucking side relative to the plurality of pairs of chucking electrodes in such a manner as to span across a positive electrode and a negative electrode constituting each pair of the chucking electrodes,
the vacuum processing apparatus being configured to perform predetermined processing on the object attracted and held by the chucking device.
